(19) United States
(12) Patent Application Publication
(10) Pub. No.: US 2025/0294698 A1
(43) Pub. Date: Sep. 18, 2025

(54) CHASSIS OF AN INFORMATION PROCESSING DEVICE HAVING MODULAR PANEL SECTION

(71) Applicant: HEWLETT PACKARD ENTERPRISE DEVELOPMENT LP, Spring, TX (US)

(72) Inventors: Minh H. Nguyen, Katy, TX (US); Vincent Nguyen, Spring, TX (US)

(21) Appl. No.: 18/602,206

(22) Filed: Mar. 12, 2024

(51) Int. Cl. H05K 7/14

(52) U.S. Cl. CPC H05K 7/1489

(57) ABSTRACT

A chassis includes a base and a modular panel section having vertical support members, a horizontal support structure, partition brackets, and bracket mounting locations. The vertical support members are coupled to the base to define an opening therebetween. The horizontal support structure extends between and coupled to the vertical support members to divide the opening into a first region and a second region. The bracket mounting locations are defined in the first and/or second regions, and each bracket mounting location includes mounting elements configured to connect one of the partition brackets to the base and/or the horizontal support structure. The partition brackets are disposed at respective bracket mounting locations and removably coupled to the base and/or to the horizontal support structure and divide the first and/or second regions into bays. Each bay is configured to receive and allow an electronic module to be electrically connected to an information processing device.

### BACKGROUND

A chassis of an information processing device such as a computer, a networking device, or the like may be configured to allow electronic modules such as line cards, solid state drives (“SSDs”), open compute program (OCP) modules, or the like, to be removably installed in the information processing device. For example, a rear panel of the chassis may have multiple openings to allow the electronic modules to be removably mounted to bays of the information processing device through the rear panel and connected to a primary system board of the information processing device. Thus, the rear panel of the chassis may facilitate installation and uninstallation of the electronic modules in the information processing device.

### BRIEF DESCRIPTION OF THE DRAWINGS

Various examples will be described below with reference to the following figures.

FIG. 1 illustrates a block diagram of a modular panel section according to an example of the present disclosure.

FIG. 2A illustrates a block diagram of a first chassis including the modular panel section of FIG. 1 in a first configuration according to an example of the present disclosure.

FIG. 2B illustrates a block diagram of a second chassis including the modular panel section of FIG. 1 in a second configuration according to an example of the present disclosure.

FIG. 2C illustrates a block diagram of a third chassis including the modular panel section of FIG. 1 in a third configuration according to an example of the present disclosure.

FIG. 2D illustrates block diagram of a fourth chassis including the modular panel section of FIG. 1 in a fourth configuration according to an example of the present disclosure.

FIG. 3A illustrates an exploded perspective view of a modular panel section according to an example of the present disclosure.

FIG. 3B illustrates an enlarged perspective view of a partition bracket of the modular panel section of FIG. 3A according to an example of the present disclosure.

FIG. 4 illustrates a perspective view of the first chassis including the modular panel section of FIG. 3A in a first configuration according to an example of the present disclosure.

FIG. 5 illustrates a perspective view of an electronic module having a first form factor according to an example of the present disclosure.

FIG. 6 illustrates a perspective view of a plurality of second electronic modules, each having a second form factor according to an example of the present disclosure.

FIG. 7 illustrates a perspective view of an information processing device having the first chassis of FIG. 4, and a primary system board, the electronic module of FIG. 5, and the plurality of second electronic modules of FIG. 6 installed in the chassis of FIG. 4 and electrically connected to the first primary system board according to an example of the present disclosure.

FIG. 8 illustrates a perspective view of a second chassis including the modular panel section of FIG. 3A in a second configuration according to an example of the present disclosure.

FIG. 9 illustrates a perspective view of a third electronic module having a third form factor according to an example of the present disclosure.

FIG. 10 illustrates a perspective view of a second information processing device having the second chassis of FIG. 8, and a second primary system board, the electronic module of FIG. 5, and the third electronic module of FIG. 9 installed in the second chassis of FIG. 8 and electrically connected to the second primary system board according to an example of the present disclosure.

FIG. 11 illustrates a perspective view of a third chassis including the modular panel section of FIG. 3A in a third configuration according to an example of the present disclosure.

FIG. 12 illustrates a perspective view of a fourth electronic module having a fourth form factor according to an example of the present disclosure.

FIG. 13 illustrates a perspective view of a third information processing device having the third chassis of FIG. 11, and a third primary system board, the fourth electronic module of FIG. 12 and the second electronic module of FIG. 6 installed in the third chassis of FIG. 11 and electrically connected to the third primary system board according to an example of the present disclosure.

FIG. 14 is a flowchart depicting a method of configuring a chassis of an information processing device by a modular panel section according to an example of the present disclosure.

### DETAILED DESCRIPTION

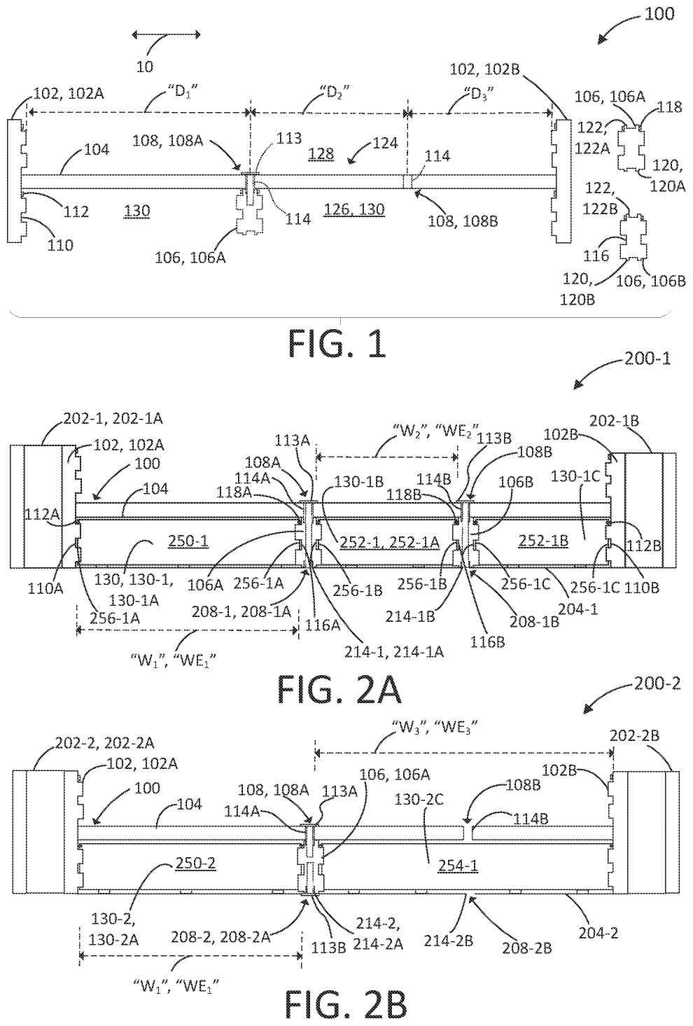

The following detailed description refers to the accompanying drawings. For purposes of explanation, certain examples are described with reference to the components illustrated in FIGS. 1-14. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the disclosed examples may be defined by the appended claims.

Generally, the rear panel is rigidly coupled to sidewalls of the chassis. The rear panel of an information processing device is generally not just a simple wall—rather, the rear panel may include a variety of interconnected structures which perform a variety of functions, including providing electromagnetic interference (EMI) shielding, providing electrical/optical connection interfaces for the information processing device, allowing airflow through the chassis, and defining rear-accessible bays to receive removable modules. A rear wall defined by the rear panel may have multiple openings in a predetermined arrangement aligned with the bays to allow electronic modules having specific form factors to be installed in the bays through the rear panel.

In particular, the bays and the openings aligned therewith are usually each configured to receive one specific form factor of electronic module and may not be compatible with other form factors. For example, one opening in the rear panel may be configured to allow an electronic module having a first height and a first width, another opening in the rear panel may be configured to allow an electronic module having the first height and a second width, yet another opening may be configured to receive an electronic module having a second height and the first width, yet another opening may be configured to receive an electronic module having the second height and the second width, and so on. In addition, even if an electronic module having the wrong form factor may physically fit within a given opening and bay, it may nevertheless not be compatible with the bay because the module might not be capable of properly engaging with attachment features or electronic connectors of the bay.

Accordingly, once the rear panel is rigidly coupled to the chassis, the configuration of electronic modules that can be used in the information processing device are also essentially fixed. Thus, users may be limited in the types of electronic modules that may be installed in a given chassis. This reduces the flexibility of the information processing device and may also inhibit future upgrades or changes to the information processing device. For example, if a user desires to modify an existing information processing device by upgrading from one electronic module to another newer electronic module with a different form factor, the user may not be able to make this upgrade without obtaining an entirely new chassis (or making extensive modifications to the existing chassis) because the newer electronic module may not be compatible with the rear panel of the existing chassis. In addition, manufacturers that would like to provide information processing device having multiple different configuration options for the electronic modules may have to design and manufacture multiple different chassis to accommodate these different configurations, which imposes additional costs and may require having multiple SKUs for the various chassis. Additionally, some rear panels are rigidly coupled only to the sidewalls of the chassis, and in such cases the rear panel may not be robust to withstand shock and vibrations, and may have a low yield strength, thereby resulting in sagging of the rear panel and/or permanent deformation of the rear panel in a fully loaded configuration of the electronic modules.

A technical solution to the aforementioned problems includes providing a customizable modular rear panel section which can be selectively changed between multiple different configurations which define different arrangements of rear-accessible bays. These different arrangements of rear-accessible bays may accommodate different types of form factors of electronic modules (e.g., different module widths) and/or different installation positions of the electronic modules. Moreover, these different configurations of the modular rear panel section can all be connected to the same main chassis section, together forming the overall chassis of the information processing device. Thus, a same overall chassis may be configured and/or reconfigured (by reconfiguring the modular rear panel section thereof) to allow installation of one or more electronic modules of varying form factors (e.g., varying widths). In other words, the same chassis may be used to form multiple different information processing system configurations which have mutually different types and/or installation locations of rear-accessible electronic modules. The modular panel section may form or may be a part of a rear panel of the information processing device.

In some examples, the chassis may be configured and/or reconfigured between a first configuration in which a full-width electronic module is accommodated and a second configuration in which two half-width electronic modules are accommodated in the same general position which received the full-width electronic module in the first configuration. In particular, in some examples, the chassis that is configured by the modular panel section may be configurable to allow installation of various combinations of open compute project (OCP) electronic modules, such as an OCP datacenter secure control module (DC SCM), an SFF OCP NIC (small-form-factor OCP network interface card), doublewide or LFF (large form factor) OCP NIC, and an OCP PCM (platform control module). For example, in a first configuration the chassis may be able to receive a DC-SCM and a LFF OCP NIC, while in a second configuration the chassis may be able to receive the DC-SCM and two of the SFF OCP NIC.

The ability of a different configurations of the chassis to allow installation of different form factors of electronics modules in the information processing device may be provided by one or more partition brackets of the modular panel section that may be arranged on a base of the chassis and/or a horizontal support structure of the modular rear panel section to define a plurality of bays for installation of the electronic modules of different form factors in the information processing device. In particular, the base and/or the horizontal support structure may include a plurality of bracket mounting locations, each having one or more mounting elements configured to, on condition of one of the partition brackets being disposed at a respective bracket mounting location, connect a respective partition bracket to the base and/or the horizontal support structure. When one or more partition brackets are attached to corresponding bracket mounting locations, they define the plurality of bays i.e., each of the spaces between a pair of adjacent partition brackets and each of the spaces between a partition bracket and an outer support structure corresponds to one bay for installation of the electronic module having different form factors. The arrangement of bays in the rear panel section may thus depend on how many partition brackets are attached and which bracket mounting locations to which they are mounted to. In other words, at least one of respective sizes of the bays, respective locations of the bays, or a number of the bays is reconfigurable (or re-customized) by varying the number of partition brackets or changing which of the bracket mounting locations the partition brackets are installed at. This can, in some examples, allow for variation in the form factor of electronic module which can be installed in an information processing device by changing the arrangement of bays. In some examples, the partition brackets that are removably coupled to the base and/or the horizontal support structure may define a honeycomb like cross sectional bays in the chassis making it stronger than a conventional rear panel.

In some examples, the modular rear panel section includes a pair of vertical support members coupled to the base and defining an opening therebetween, and a horizontal support structure extending between and coupled to the pair of vertical support members to divide the opening into a first region and a second region. In such examples, the partition brackets are disposed at respective bracket mounting locations of the plurality of bracket mounting locations defined in the first region and/or the second region and removably coupled to the base and/or to the horizontal support structure and divide the first region and/or the second region into the plurality of bays. Further, each bay is configured to receive the electronic module and allow the electronic module to be electrically connected to a primary system board of the information processing device. In such examples, each vertical support member may include a first guide member, and each partition bracket may include second guide members, where the first and second guide members may be configured to engage with third guide members of the electronic module as the plurality of electronic modules is inserted into the plurality of bays to mount the plurality of electronic modules to the information processing device. Additionally, each partition bracket and/or vertical support member may include a latching element configured to secure the electronic module received in a corresponding bay.

Since the modular panel section provides the options to configure (or reconfigure) the chassis for accommodating different form factor electronic modules in the chassis, it provides flexibility to upgrade the existing electronic modules of varying form factors without changing the chassis. As the chassis can be reconfigured to support electronic modules of varying form factors, next generation electronic modules may be designed to any of the known form factors to easily fit into existing chassis. Hence, cost incurred from redesigning of a chassis, based on the varying form factors of the electronic modules may be avoided. Further, the chassis designed may extend to the lifecycle of a single chassis, providing substantial cost saving for the next generation of electronic modules. Additionally, the chassis may provide support to an extensive range of electronic modules, such as an OCP DC SCM, an SFF OCP NIC, doublewide or LFF OCP NIC, and an OCP PCM. Additionally, since the modular panel section is customized by coupling the one or more partition brackets to the base and the horizontal support structure, the modular panel section is robust enough to withstand shock and vibrations, and may have a high yield strength, thereby overcoming the problems in a convention chassis of having sagged rear panel and/or permanent deformed rear panel, when the conventional chassis in a fully loaded configuration of the electronic modules.

Referring to Figures, FIG. 1 depicts a block diagram of a modular panel section 100 of a chassis. It should be understood that FIG. 1 is not intended to illustrate specific shapes, dimensions, or other structural details accurately or to scale and that implementations of the modular panel section 100 may have different numbers and arrangements of the illustrated components and may also include other parts that are not illustrated. In some examples, the modular panel section 100 forms a rear panel of an information processing device such as a computer (e.g., a server, a storage device), a networking device (e.g., a switch, an access point), or the like. In some other examples, the modular panel section 100 may be a part of the rear panel of the information processing device. In other words, the modular panel section forms or is a part of a rear panel of the information processing device. The modular panel section 100 includes a pair of vertical support members 102, a horizontal support structure 104, one or more partition brackets 106, and a plurality of bracket mounting locations 108.

Each vertical support member 102 is a support beam of the modular panel section 100. In some examples, each vertical support member 102 may be part of a corresponding component housing of the information processing device or may be a discrete member that may be coupled to the component housing. In other words, one vertical support member of the pair of vertical support members 102 is part of one component housing of the pair of component housings. Each vertical support member 102 includes a first guide member 110 (e.g., groove) configured to slidably receive a portion of an electronic module and a latching element, for example, a first latching element 112 configured to secure the received electronic module.

The horizontal support structure 104 is a load bearing beam of the modular panel section 100. The horizontal support structure 104 extends horizontally between, and is coupled to, vertical support members 102. The horizontal support structure 104 may be configured to cover the electronic module disposed on a base of the chassis and/or may additionally be configured to house the electronic module. In addition, the horizontal support structure 104 may vertically divide the rear panel section 100 into two regions, i.e., a lower region below the horizontal support structure 104 and an upper region above the horizontal support structure 104 and may separate electronic modules installed in one region from the electronic modules installed in another region.

Each partition bracket 106 is an intermediate support beam of the modular panel section 100. In some examples, each partition bracket 106 includes a second guide member 116 (e.g., guide groove) configured to slidably receive another portion of the electronic module, another latching element, for example, a second latching element 118 configured to secure the received electronic module. Further, each partition bracket 106 includes a bottom mounting feature 120 and a top mounting feature 122, each configured to be connected to the base and/or the horizontal support structure 104, and thereby create one or more bays for receiving and removably installing the electronic modules to the information processing device. In some examples, the bottom and top mounting features 120, 122 of each partition bracket 106 may include a hole (not labeled) to receive fastener and connect the partition bracket 106 to the horizontal support structure 104 and base and/or a cover of the chassis.

At least some of the bracket mounting locations 108 are arranged in the horizontal support structure 104. In some examples, additional bracket mounting locations 108 may be arranged in the base and/or the cover. In some of these examples, such additional bracket mounting locations may be configured to align with the corresponding bracket mounting locations 108 in the horizontal support structure 104. In the example of FIG. 1, the modular panel section 100 is shown to include two bracket mounting locations 108A, 108B. In some other examples, the modular panel section 100 may include more than one bracket mounting locations 108 in the horizontal support structure 104, the base, and/or the cover, and such bracket mounting locations 108 may be chosen based on different form factors of the electronic modules. Further, the bracket mounting locations 108 are distanced from each other along a width of the horizontal support structure 104 extending in a first direction 10 of the horizontal support structure 104. Similarly, each bracket mounting location 108 is distanced from the corresponding vertical support member 102 along the width of the horizontal support structure 104. In the example of FIG. 1, a first bracket mounting location 108A is distanced from a first vertical support member 102A by a distance “D₁”, the first bracket mounting location 108A and a second bracket mounting location 108B are distanced from each other by a distance “D₂”, and the second bracket mounting location 108B is distanced from a second vertical support member 102B by a distance “D₃”. In some examples, the distance “D₁” is greater than each of the distances “D₂” and “D₃”. Further, in some examples, the distances “D₂” and “D₃” are equal.

Each bracket mounting location 108 includes one or more mounting elements 114. Each mounting element 114 is configured to facilitate connection of a partition bracket 106 to the horizontal support structure 104, either by directly engaging with the partition bracket 106 or by engaging with another element (such as a fastener 113) which in turn engages with the partition bracket 106. An example of a mounting element 114 which engages directly with the partition bracket 106 is a groove or protrusion which mates with a complementary protrusion or groove of the partition bracket 106 (e.g., such as in a dovetail joint). Another example of a mounting element 114 which engages directly with the partition bracket 106 is a latch which engages the partition bracket 106. An example of a mounting element 114 which engages indirectly with the partition bracket 106 via another element is a hole which receives a fastener (e.g., screw) which extends down through the hole of the mounting element 114 and engages the partition bracket 106. For instance, FIG. 1 illustrates one example in which partition bracket 106A is mounted to mounting location 108A by a fastener 113 extending through mounting element 114 and engaging top mounting feature 120 of the partition bracket 106A.

In some examples, the modular panel section 100 is assembled by first mounting the pair of vertical support members 102 (which are spaced from each other) on the base of a chassis of an information processing system and coupling the pair of vertical support members 102 to the base such that an opening 124 is defined therebetween. Further, the horizontal support structure 104 is disposed in the opening 124 such that it extends between the pair of vertical support members 102 and coupled to the pair of vertical support members 102 to divide the opening 124 into a first region 126 and a second region 128. Further, one or more partition brackets 106 are disposed at the plurality of bracket mounting locations 108. In the example of FIG. 1, a first partition bracket 106A is disposed at the first bracket mounting location 108A. In some examples, the one or more mounting elements 114 is configured to, on condition of one of the partition brackets 106 being disposed at a respective bracket mounting location 108, connect a respective partition bracket 106 to the horizontal support structure 104. In particular, in some examples the modular panel section 100 may include fasteners 113 that may extend through the holes in one or more mounting elements 114 and engage with either the top mounting feature 122 or the bottom mounting feature 120 of the corresponding partition bracket 106.

In some examples, different fasteners may be used to connect to the top and bottom mounting features 120 and 122. In such examples, if the partition bracket 106 is disposed below the horizontal support structure 104, the fastener 113 may extend downward through the mounting element 114 and engage the top mounting feature 122 to connect the corresponding partition bracket 106 to the horizontal support structure 104, and other fastener (not illustrated) may extend upward through the holes in the one or more mounting elements in the base and engage the bottom mounting feature 120 of the corresponding partition bracket 106 to connect the corresponding partition bracket 106 to the base. On the other hand, in these examples, if the partition bracket 106 is disposed above the horizontal support structure 104, the fastener 113 may extend upward through the mounting element 114 and engage the bottom mounting feature 120 to connect the corresponding partition bracket 106 to the horizontal support structure 104, and other fasteners (not illustrated) may extend downward through the holes in the one or more mounting elements in the cover and engage the top mounting feature 122 of the corresponding partition bracket 106 to connect the corresponding partition bracket 106 to the cover.

In other examples, a single fastener (not illustrated) may connect the partition bracket 106 to both the horizontal support structure 104 and to the base (if the partition bracket 106 is disposed below the horizontal support structure 104) or to the cover (if the partition bracket 106 is disposed above the horizontal support structure 104). In these examples, the top mounting feature 122 and bottom mounting feature 120 may be two parts of a single hole which extends through the bracket 106, and the fastener may extend through this hole. That is, if the partition bracket 106 is positioned below the horizontal support structure 104, fastener may extend downward through the hole in mounting element 114, through top mounting feature 122, through the bracket 106 and out the bottom mounting feature 120, and finally into a hole in mounting element of the base. If the partition bracket 106 is positioned above the horizontal support structure 104, the fastener may extend upward through the mounting element 114, through the bracket 106, and into a hole in the cover.

For example, the first partition bracket 106A may be disposed at the first bracket mounting location 108A in the first region 126. Further, a first fastener (not shown) may extend through the holes in the first mounting element 114A and the top mounting feature 122 and a second fastener (not shown) may extend through the holes in a first mounting element in the base (not shown), and the bottom mounting feature 120 to connect the first partition bracket 106A to the horizontal support structure 104 and the base. In some examples, when the partition brackets 106 are disposed at respective bracket mounting locations 108 and removably connected to the horizontal support structure 104 and the base, the partition brackets 106 divides the first region (and/or the second region) into a plurality of bays 130. For example, the first partition bracket 106A may divide the first region 126 into a plurality of bays 130. In particular, each of the plurality of bays 130 has the width, which may be complementary to the width of a corresponding electronic module. Accordingly, each of the plurality of bays 130 may be configured to receive an electronic module of a particular form factor (e.g., complementary width) and allow the electronic module to be electrically connected to a primary system board of the information processing device.

In some examples, at least one of respective sizes of the bays 130, respective locations of the bays 130, or a number of the bays 130 is reconfigurable by disposing a second partition bracket 106B at the second bracket mounting location 108B or removing the first partition bracket 106A from the first bracket mounting location 108A or changing the first partition bracket 106A installed at the first bracket mounting location 108A to the second bracket mounting location 108B. Thus, the modular panel section 100 provides the options to configure (or reconfigure) the chassis for accommodating different form factor electronic modules in the chassis. Further, the modular panel section 100 provides flexibility to upgrade the existing electronic modules of varying form factors without changing the chassis. As the chassis can be reconfigured to support electronic modules of varying form factors, next generation electronic modules may be designed to any of the known form factors to easily fit into existing chassis. Hence, cost incurred from redesigning of a chassis, based on the varying form factors of the electronic modules may be avoided. Further, the chassis designed may extend to the lifecycle of a single chassis, providing substantial cost saving for the next generation of electronic modules. Additionally, since the modular panel section 100 is customized by coupling the one or more partition brackets to the base and the horizontal support structure, the modular panel section 100 is robust enough to withstand shock and vibrations, and may have a high yield strength, thereby overcoming the problems in a convention chassis of having sagged rear panel and/or permanent deformed rear panel, when the conventional chassis in a fully loaded configuration of the electronic modules.

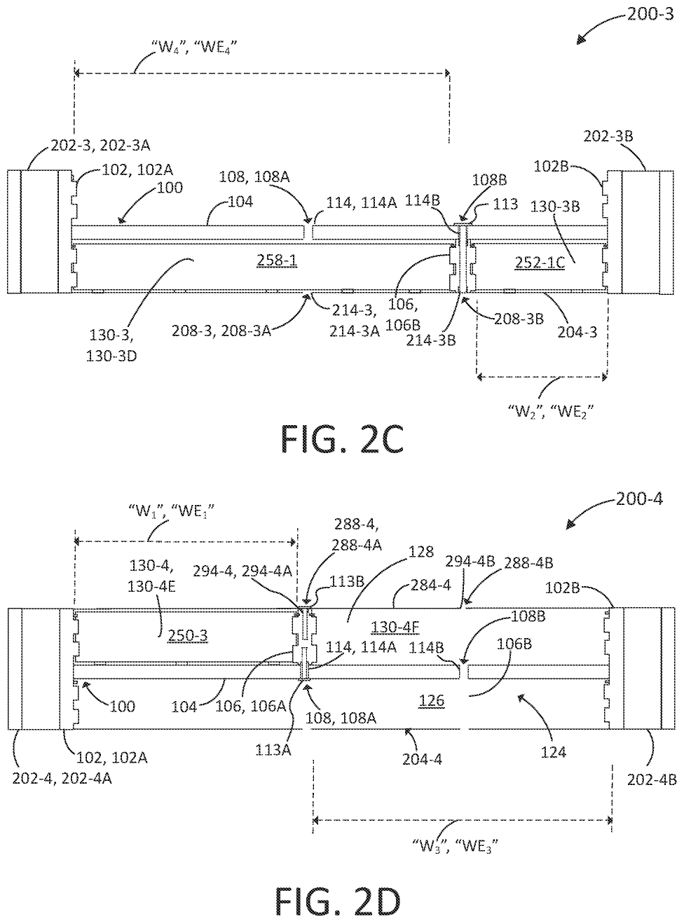

FIG. 2A depicts a block diagram of a first chassis 200-1 including and configured by a modular panel section 100 of FIG. 1 in a first configuration. The first configuration of the modular panel section 100 is one in which the two of the partition brackets 106A and 106B are mounted at bracket mounting locations 108A and 108B, respectively, and disposed below horizontal structure 104. The first chassis 200-1 includes a pair of component housings 202-1, a base 204-1, and the modular panel section 100.

In some examples, each component housing 202-1 may be a cage that is configured to house a corresponding electronic component, such as a power supply unit of the information processing device. The base 204-1 is a load bearing component of the first chassis 200-1. The base 204-1 may extend between the pair of component housings 202-1 via the modular panel section 100. The base 204-1 includes a plurality of bracket mounting locations 208, for example, a first bracket mounting location 208-1A and a second bracket mounting location 208-1B. In such examples, each of the plurality of bracket mounting locations 208-1 includes one or more mounting elements 214, for example, a first mounting element 214-1A and a second mounting element 214-1B, which may be similar to a first mounting element 114A and a second mounting element 114B disposed on the horizontal support structure 104 of FIG. 1.

The modular panel section 100 is disposed between the pair of component housings 202-1. As discussed herein, the modular panel section 100 includes the pair of vertical support members 102, the horizontal support structure 104, the one or more partition brackets 106, and the plurality of bracket mounting locations 108. In the example of FIG. 2, the pair of vertical support members 102 is part of the pair of component housings 202-1. In particular, the first vertical support member 102A is integrated to a first component housing 202-1A and the second vertical support member 102B is integrated to a second component housing 202-1B. In some examples, the pair of vertical support members 102 is disposed spaced apart from each other and coupled to the base 204-1 such that an opening 124 (as shown in FIG. 1) is defined therebetween the pair of vertical support members 102. The horizontal support structure 104 extends between and coupled to the pair of vertical support members 102 to divide the opening 124 into a first region 126 and a second region 128 (as shown in FIG. 1). In such examples, the first and second bracket mounting locations 108A, 108B of the horizontal support structure 104 are vertically aligned to the first bracket mounting location 208-1A and the second bracket mounting location 208-1B of the base 204-1. The one or more partition brackets 106 are disposed in the first region 126 at a respective bracket mounting location 108. For example, a first partition bracket 106A is disposed at first bracket mounting locations 108A, 208-1A and a second partition bracket 106B is disposed at second bracket mounting locations 108B, 208-1B, thereby dividing the first region 126 into a plurality of bays 130. In the illustrated example, the chassis includes three bays e.g., a first bay 130-1A and two second bays 130-1B, 130-1C. In such examples, the first bay 130-1A has a first width “W₁” and each of the two second bays 130-1B, 130-1C has a second width “W₂”. In some examples, the first width “W₁” is greater than the second width “W₂”. In some examples, the first partition bracket 106A is removably connected to the horizontal support structure 104 and the base 204-1 by extending a fastener 113A into the holes in the first mounting element 114A, the top mounting feature 122A (as shown in FIG. 1), the bottom mounting feature 120A (as shown in FIG. 1), and the first mounting element 214-1A. Similarly, the second partition bracket 106B is removably connected to the horizontal support structure 104 and the base 204-1 by extending another fastener 113B into the holes in the second mounting element 114B, the top mounting feature 122B (as shown in FIG. 1), the bottom mounting feature 120B (as shown in FIG. 1), and the second mounting element 214-1B.

In some examples, the first bay 130-1A is configured to slidably receive a first electronic module 250-1 having a first form factor (e.g., a first width “WE₁”), and each of the two second bays 130-1B, 130-1C is configured to slidably receive a second electronic module among a plurality of second electronic modules 252-1, each having a second form factor (e.g., a second width “WE₂”). In particular, the first guide members 110A of the first vertical support member 102A and a second guide member 116A of the first partition bracket 106A are configured to engage with third guide members 256-1A of the first electronic module 250-1 as the first electronic module 250-1 is inserted into the first bay 130-1A to mount the first electronic module 250-1 to the first chassis 200-1 of the information processing device. Similarly, the second guide members 116A of the first partition bracket 106A and a second guide members 116C of the third partition bracket 106C are configured to engage with third guide members 256B of one of the second electronic module 252-1A among the plurality of second electronic modules 252-1 as the second electronic module 252-1A is inserted into one second bay 130-1B to mount the second electronic module 250-1A to the first chassis 200-1 of the information processing device. Further, the second guide member 116B of the second partition bracket 106B and a first guide member 110B of the second vertical support member 102B are configured to engage with third guide members 256-1C of another second electronic module 252-1B among the plurality of second electronic modules 252-1 as the other second electronic module 252-1B is inserted into another second bay 130-1C to mount the other second electronic module 250-1B to the first chassis 200-1 of the information processing device. In one or more examples, as the first electronic module 250-1 is inserted into the first bay 130-1A, the first latching element 112A and the second latching element 118A are configured to engage with the groove (not labeled) in the first electronic module 250-1 and secure the first electronic module 250-1 to the first chassis 200-1. Further, as the first electronic module 250-1 is disposed in the first bay 130-1A, the first electronic module 250-1 is electrically connected to a primary system board of the information processing device. In particular, an electrical connector (not shown) of the first electronic module 250-1 is directly connected to another electrical connector (not shown) of the primary system board. Similarly, as the second electronic module 252-1A is inserted into the one second bay 130-1B, the second latching element 118A of the first partition bracket 106A and the second latching element 118B of the second partition bracket 106B are configured to engage with the groove (not labeled) in the second electronic module 252-1A and secure the second electronic module 252-1A to the first chassis 200-1. In some examples, as the second electronic module 252-1A is disposed in the one second bay 130-1B, the second electronic module 252-1A is electrically connected to the primary system board of the information processing device. In particular, an electrical connector (not shown) of the second electronic module 252-1A is directly connected to another electrical connector (not shown) of the primary system board. Further, as the other second electronic modules 252-1B is inserted into the other second bay 130-1C, the second latching element 118B of the second partition bracket 106B and the first latching element 112B of the second vertical support member 102B are configured to engage with the groove (not labeled) in the other second electronic module 252-1B and secure the other second electronic module 252-1B to the first chassis 200-1. In some examples, as the other second electronic module 252-1B is disposed in the other second bay 130-1C, the other second electronic module 252-1B is electrically connected to the primary system board of the information processing device. In particular, an electrical connector (not shown) of the other second electronic module 252-1B is directly connected to another electrical connector (not shown) of the primary system board. In some examples, the first electronic module 250-1 may be an open compute program (OCP) datacenter secure control module (DC SCM) and each of the plurality of second electronic modules 252-1 may be an SFF OCP NIC (small-form-factor OCP network interface card).

FIG. 2B depicts a block diagram of a second chassis 200-2 including (configured by) a modular panel section 100 of FIG. 1 in a second configuration. The second configuration is one in which partition bracket 106A is mounted to mounting location 108A below structure 104, while mounting location 108B below structure 104 is not utilized. The second chassis 200-2 includes a pair of component housings 202-2, a base 204-2, and the modular panel section 100.

In some examples, each component housing 202-2 may be a cage that is configured to house a corresponding electronic component, such as a power supply unit of the information processing device. The base 204-2 is a load bearing component of the second chassis 200-2. The base 204-2 includes a plurality of bracket mounting locations 208-2, for example, a first bracket mounting location 208-2A and a second bracket mounting location 208-2B. In such examples, each of the plurality of bracket mounting locations 208-2 includes one or more mounting elements 214-2, for example, a first mounting element 214-2A and a second mounting element 214-2B, which are similar to a first mounting element 114A and a second mounting element 114B disposed on the horizontal support structure 104 of FIG. 1.

The modular panel section 100 is disposed between the pair of component housings 202-2. As discussed herein, the modular panel section 100 includes the pair of vertical support members 102, the horizontal support structure 104, the one or more partition brackets 106, and the plurality of bracket mounting locations 108. In some examples, the pair of vertical support members 102 is disposed spaced apart from each other and coupled to the base 204-2 such that an opening 124 (as shown in FIG. 1) is defined therebetween the pair of vertical support members 102. The horizontal support structure 104 extends between and coupled to the pair of vertical support members 102 to divide the opening 124 into a first region 126 and a second region 128 (as shown in FIG. 1). In such examples, the first and second bracket mounting locations 108A, 108B of the horizontal support structure 104 are vertically aligned to the first bracket mounting location 208-2A and the second bracket mounting location 208-2B of the base 204-2. The one or more partition brackets 106 are disposed in the first region 126 at a respective bracket mounting location 108. For example, a first partition bracket 106A is disposed at first bracket mounting locations 108A, 208-2A, thereby dividing the first region 126 into a plurality of bays 130-2. In the illustrated example, the chassis includes two bays e.g., a first bay 130-2A and a third bay 130-2C. In such examples, the first bay 130-2A has a first width “W₁” and the third bay 130-2C has a third width “W₃”. In some examples, the third width “W₃” is greater than the first width “W₁”. In some examples, the first partition bracket 106A is removably connected to i) the horizontal support structure 104 by extending one fastener 113A into the holes in the first mounting element 114A and the top mounting feature 122A (as shown in FIG. 1) and ii) the base 204-2 by extending another fastener 113B into the holes in the first mounting element 214-2A and the bottom mounting feature 120A. In other words, the fastener 113A extends downward through the first mounting element 114A and engages the top mounting feature 122A to connect the first partition bracket 106A to the horizontal support structure 104, and other fastener 113B extends upward through the holes in the first mounting element 214-2A and engages the bottom mounting feature 120A to connect the first partition bracket 106A to the base 204-2.

In some examples, the first bay 130-2A is configured to slidably receive a first electronic module 250-2 having a first form factor (e.g., a first width “WE₁”), and the third bay 130-2C is configured to slidably receive a third electronic module 254-1 having a third form factor (e.g., a third width “WE₃”). It may be noted herein that the first electronic module 250-2 is similar to the first electronic module 250-1 (as shown in FIG. 2A). Further, the first bay 130-2A has the same width as that of the first bay 130-1A of FIG. 1. As the first electronic module 250-2 is disposed in the first bay 130-2A, the first electronic module 250-2 is electrically connected to a primary system board of the information processing device. In particular, an electrical connector (not shown) of the first electronic module 250-2 is directly connected to another electrical connector (not shown) of the primary system board. Further, as the third electronic module 254-1 is disposed in the third bay 130-2C, the third electronic module 254-1 is electrically connected to the primary system board of the information processing device. In particular, an electrical connector (not shown) of the third electronic module 254-1 is directly connected to another electrical connector (not shown) of the primary system board. In some examples, the first electronic module 250-2 may be an open compute program (OCP) datacenter secure control module (DC SCM) and the third electronic module 252-2 may be doublewide or LFF (large form factor) OCP network interface card (NIC).

FIG. 2C depicts a block diagram of a third chassis 200-3 including (configured by) a modular panel section 100 of FIG. 1 in a third configuration. The third configuration is one in which a partition bracket 106B is mounted to mounting location 108B below structure 104, while mounting location 108A below structure 140 is unused. The third chassis 200-3 includes a pair of component housings 202-3, a base 204-3, and the modular panel section 100.

In some examples, each component housing 202-3 may be a cage that is configured to house a corresponding electronic component, such as a power supply unit of the information processing device. The base 204-3 is a load bearing component of the third chassis 200-3. The base 204-3 includes a plurality of bracket mounting locations 208-3, for example, a first bracket mounting location 208-3A and a second bracket mounting location 208-3B. In such examples, each of the plurality of bracket mounting locations 208-3 includes one or more mounting elements 214-3, for example, a first mounting element 214-3A and a second mounting element 214-3B, which are similar to a first mounting element 114A and a second mounting element 114B disposed on the horizontal support structure 104 of FIG. 1.

The modular panel section 100 is disposed between the pair of component housings 202-3. As discussed herein, the modular panel section 100 includes the pair of vertical support members 102, the horizontal support structure 104, the one or more partition brackets 106, and the plurality of bracket mounting locations 108. In some examples, the pair of vertical support members 102 is disposed spaced apart from each other and coupled to the base 204-3 such that an opening 124 (as shown in FIG. 1) is defined therebetween the pair of vertical support members 102. The horizontal support structure 104 extends between and coupled to the pair of vertical support members 102 to divide the opening 124 into a first region 126 and a second region 128 (as shown in FIG. 1). In such examples, the first and second bracket mounting locations 108A, 108B of the horizontal support structure 104 are vertically aligned to the first bracket mounting location 208-3A and the second bracket mounting location 208-3B of the base 204-3. The one or more partition brackets 106 are disposed in the first region 126 at a respective bracket mounting location 108. For example, a second partition bracket 106B is disposed at second bracket mounting locations 108B, 208-3A, thereby dividing the first region 126 into a plurality of bays 130-3. In the illustrated example, the chassis includes two bays e.g., a fourth bay 130-3D and a second bay 130-3B. In such examples, the fourth bay 130-3D has a fourth width “W₄” and the second bay 130-3B has a second width “W₂”. In some examples, the fourth width “W₄” is greater than the second width “W₂”. In some examples, the second partition bracket 106B is removably connected to the horizontal support structure 104 and the base 204-3 by extending a fastener 113 into the holes in the second mounting element 114B, the top mounting feature 122A (as shown in FIG. 1), the bottom mounting feature 120A (as shown in FIG. 1), and the first mounting element 214-3B.

In some examples, the fourth bay 130-3D is configured to slidably receive a fourth electronic module 258-1 having a fourth form factor (e.g., a fourth width “WE₄”), and the second bay 130-3B is configured to slidably receive a second electronic module 252-1C having a second form factor (e.g., a second width “WE₂”). It may be noted herein that the second electronic module 252-1C is similar to the second electronic module 252-1A, 252-1B (as shown in FIG. 2A). Further, the second bay 130-3B has the same width as that of the second bay 130-1B, 130-1C of FIG. 1. As the fourth electronic module 258-1 is disposed in the fourth bay 130-3D, the fourth electronic module 258-1 is electrically connected to a primary system board of the information processing device. In particular, an electrical connector (not shown) of the fourth electronic module 258-1 is directly connected to another electrical connector (not shown) of the primary system board. Further, as the second electronic module 252-1C is disposed in the second bay 130-3B, the second electronic module 252-1C is electrically connected to the primary system board of the information processing device. In particular, an electrical connector (not shown) of the second electronic module 252-1C is directly connected to another electrical connector (not shown) of the primary system board. In some examples, the fourth electronic module 258-1 may be an OCP PCM (platform control module) and the second electronic module 252-1C may be SFF OCP NIC (small-form-factor OCP network interface card).

FIG. 2D depicts a block diagram of a fourth chassis 200-4 configured by a modular panel section 100 of FIG. 1 in a fourth configuration. The fourth configuration is one in which partition bracket 106A is mounted to bracket mounting location 106A above structure 104. The fourth chassis 200-4 includes a pair of component housings 202-4, a base 204-4, a cover 284-4, and the modular panel section 100.

In some examples, each component housing 202-4 may be a cage that is configured to house a corresponding electronic component, such as a power supply unit of the information processing device. The base 204-4 is a load bearing component of the fourth chassis 200-4 and the cover 284-4 is a protective lid of the fourth chassis 200-4. The cover 204-4 includes a plurality of bracket mounting locations 288-4, for example, a first bracket mounting location 288-4A and a second bracket mounting location 288-4B. In such examples, each of the plurality of bracket mounting locations 288-4 includes one or more mounting elements 294-4, for example, a first mounting element 294-4A and a second mounting element 294-4B, which are similar to a first mounting element 114A and a second mounting element 114B disposed on the horizontal support structure 104 of FIG. 1.

The modular panel section 100 is disposed between the pair of component housings 202-4. As discussed herein, the modular panel section 100 includes the pair of vertical support members 102, the horizontal support structure 104, the one or more partition brackets 106, and the plurality of bracket mounting locations 108. In some examples, the pair of vertical support members 102 is disposed spaced apart from each other and coupled to the cover 284-4 such that an opening 124 is defined therebetween the pair of vertical support members 102. The horizontal support structure 104 extends between and coupled to the pair of vertical support members 102 to divide the opening 124 into a first region 126 and a second region 128 (as shown in FIG. 1). In such examples, the first and second bracket mounting locations 108A, 108B of the horizontal support structure 104 are vertically aligned to the first bracket mounting location 288-4A and the second bracket mounting location 288-4B of the cover 284-4. The one or more partition brackets 106 are disposed in the second region 128 at a respective bracket mounting location 108. For example, a first partition bracket 106A is disposed at first bracket mounting locations 108B, 288-4A, thereby dividing the second region 128 into a plurality of bays 130-4. In the illustrated example, the chassis includes two bays e.g., a fifth bay 130-4E and a sixth bay 130-4F. In such examples, the fifth bay 130-4E has a first width “W₁” and the sixth bay 130-4F has a third width “W₃”. In some examples, the third width “W₃” is greater than the first width “W₁”. In some examples, the first partition bracket 106A is removably connected to i) the horizontal support structure 104 by extending one fastener 113A into the holes in the first mounting element 114A and the bottom mounting feature 120A (as shown in FIG. 1) and ii) the cover 284-4 by extending another fastener 113B into the holes in the first mounting element 294-4A and the top mounting feature 122A (as shown in FIG. 1). In other words, the fastener 113A extends upwards through the holes in the first mounting element 114A and engages the bottom mounting feature 120A to connect the first partition bracket 106A to the horizontal support structure 104 and other fastener 113A extends downwards through the holes in the first mounting element 294-4A and engages the top mounting feature 122A to connect the first partition bracket 106A to the cover 284-4.

In some examples, the fifth bay 130-4E is configured to slidably receive a first electronic module 250-3 having a first form factor (e.g., a first width “WE₁”). It may be noted herein that the first electronic module 250-3 is similar to the first electronic module 250-1 (as shown in FIG. 2A). Further, the sixth bay 130-4F has the same width as that of the third bay 130-2C of FIG. 2B. After, the first electronic module 250-3 is disposed in the fifth bay 130-4E, the first electronic module 250-3 is electrically connected to a primary system board of the information processing device. In particular, an electrical connector (not shown) of the first electronic module 250-3 is connected to another electrical connector (not shown) of the primary system board via cables. Since the first electronic module 250-3 is disposed in the second region 128, the electrical connector of the first electronic module 250-3 may not be directed connected to the electrical connector of the primary system board, therefore the cable may have to be used to connect the first electronic module 250-3 to the primary system board. In some examples, the first electronic module 250-3 may be an open compute program (OCP) datacenter secure control module (DC SCM). The sixth bay 130-4F may receive the third electronic module 254-2 such as doublewide or LFF (large form factor) OCP network interface card (NIC).

Referring to Figures, FIGS. 2A-2D, in one or more examples, at least one of respective sizes of the bays 130, respective locations of the bays 130, or a number of the bays among the plurality of bays 130 is reconfigurable (or re-customized) to allow installation of the one or more electronic modules of varying form factors by at least one of: i) disposing an additional partition bracket 106 at one of the plurality of bracket mounting locations 108 or removing one of the partition brackets 106 or ii) changing which of the plurality of bracket mounting locations 108 the one or more partition brackets 106 are installed at. Thus, the modular panel section 100 provides the options to configure (or reconfigure) the chassis for accommodating different form factor electronic modules in the chassis, it provides flexibility to upgrade the existing electronic modules of varying form factors without changing the chassis. As the chassis can be reconfigured to support electronic modules of varying form factors, next generation electronic modules may be designed to any of the known form factors to easily fit into existing chassis. Hence, cost incurred from redesigning of a chassis, based on the varying form factors of the electronic modules may be avoided. Further, the chassis designed may extend to the lifecycle of a single chassis, providing substantial cost saving for the next generation of electronic modules. Additionally, since the modular panel section is customized by coupling the one or more partition brackets to the base, the cover, and the horizontal support structure, the modular panel section is robust enough to withstand shock and vibrations, and may have a high yield strength, thereby overcoming the problems in a convention chassis of having sagged rear panel and/or permanent deformed rear panel, when the conventional chassis in a fully loaded configuration of the electronic modules.

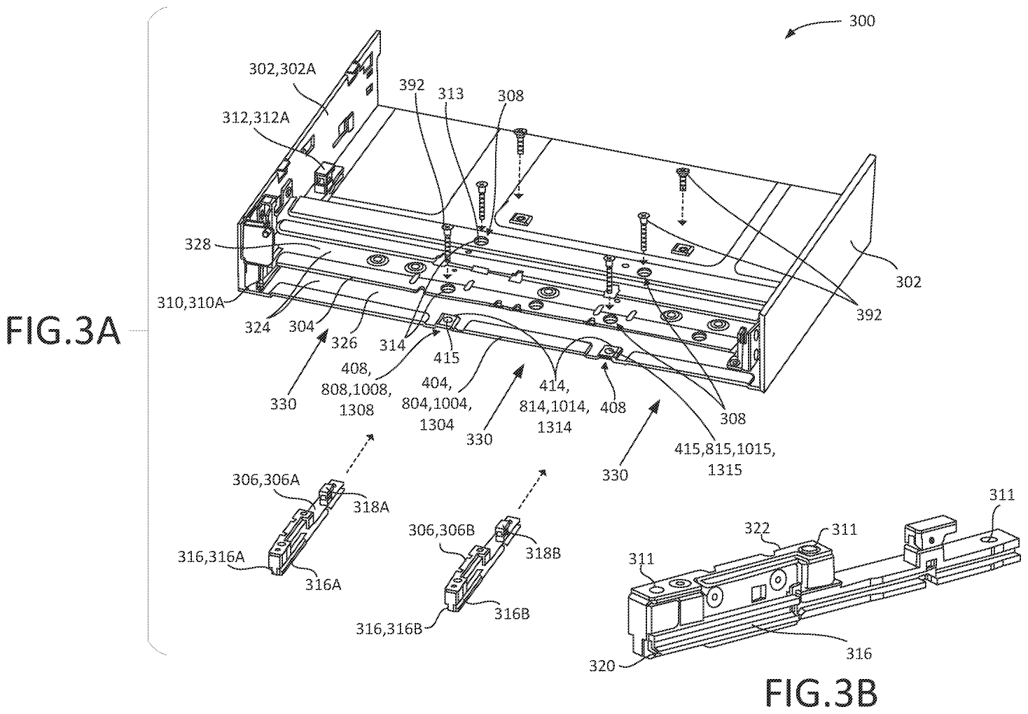

FIGS. 3A and 3B depict a modular panel section 300. FIG. 3A depicts an exploded perspective view of the modular panel section 300, while FIG. 3B depicts an enlarged perspective view of a partition bracket 306 of the modular panel section 300. In the description hereinafter, FIGS. 3A and 3B are described concurrently for ease of illustration. The modular panel section 300 includes a pair of vertical support members 302, a horizontal support structure 304, one or more partition brackets 306, a plurality of bracket mounting locations 308, 408 (and/or 808, 1008, 1308) one or more mounting elements 314, and one or more fasteners 392. It may be noted herein that a portion of a base 404 (and/or 804, 1004, 1304) of a chassis is also shown in the example of FIG. 3A for ease of explanation of the disclosure and such disclosure of the base 404 with the modular panel section 300 should not be construed as a limitation of the present disclosure. Further, it may be noted herein that the one or more fasteners 392 that are used to removably connect the one or more partition brackets 306 to the horizontal support structure 304 are only shown in the example of FIG. 3A and other one or more fasteners that may be used to removably connect the one or more partition brackets 306 to the base 404 and/or to the cover are not shown in the example of FIG. 3A for ease of illustration and such non-illustration of such one or more fasteners should not be construed as a limitation of the present disclosure.

Each vertical support member 302 includes a first guide member 310 (e.g., groove) to slidably receive a portion of an electronic module, and a latching element, for example, a first latching element 312 to secure the received electronic module. The horizontal support structure 304 covers the electronic module disposed on the base 404 of the chassis and/or houses the electronic module disposed on the horizontal support structure 304. Each partition bracket 306 includes a second guide member 316 (e.g., guide groove) to slidably receive another portion of the electronic module, a latching element, for example, a second latching element 318 to secure the received electronic module. Each partition bracket 306 further includes a bottom mounting feature 320 and a top mounting feature 322, each configured to be connected to the horizontal support structure 304 and to the base 404 and/or a cover, and thereby create a plurality of bays 330 to allow the electronic modules to be removably installed to the information processing device. In some examples, the bottom and top mounting features 320, 322 of each partition bracket 306 includes a hole 311. Further, each partition bracket 306 has a half U space height.

In some examples, some bracket mounting locations 308 are in the horizontal support structure 304 and some other bracket mounting locations 408 are in the base 404. Further, the modular panel section 300 may additionally include bracket mounting locations in a cover of the chassis. In such examples, the bracket mounting locations 308 in the horizontal support structure 304 and the base 404 and/or the cover are vertically aligned to each other. Each bracket mounting location 308 in the horizontal support structure 304 includes one or more mounting elements 314. In some examples, each of the one or more mounting elements 314 has a hole 313. Similarly, the bracket mounting locations 408 in the base 404 includes one or more mounting elements 414 (and/or 814, 1014, 1314). In some examples, each of the one or more mounting elements 414 has a hole 415 (and/or 815, 1015, 1315).

In some examples, the modular panel section 300 is assembled by first mounting the pair of vertical support members 302 on the base 404 and coupling the pair of vertical support members 302 to the base 404 such that an opening 324 is defined therebetween. Further, the horizontal support structure 304 is disposed in the opening 324 such that it extends between the pair of vertical support members 302 and coupled to the pair of vertical support members 302 to divide the opening 324 into a first region 326 and a second region 328. Further, one or more partition brackets 306 may be disposed in the first region 326 and/or the second region 328 at the plurality of bracket mounting locations 308, 408. In such examples, the one or more mounting elements 314, 414 are configured to, on condition of one of the partition brackets 306 being disposed at a respective bracket mounting locations 308, 408, connect a respective partition bracket 306 to the horizontal support structure 304 and base 404 and/or the cover. For example, the modular panel section 300 includes fasteners 392 that may extend through the holes 313 in one or more mounting elements 314 and holes 311 in the top mounting feature 322 to connect a top portion of the corresponding partition bracket 306 to the horizontal support structure 304. Similarly, the modular panel section 300 includes other fasteners that may extend through the holes 415 in one or more mounting elements 414 and holes (not shown) in the bottom mounting feature 320 to connect a bottom portion of the corresponding partition bracket 306 to the base 404. In some examples, when the partition brackets 306 are disposed at respective bracket mounting locations 308, 408 and removably connected to the horizontal support structure 304 and the base 404, the partition brackets 306 may divide the first region 326 (and/or the second region 328) into the plurality of bays 330.

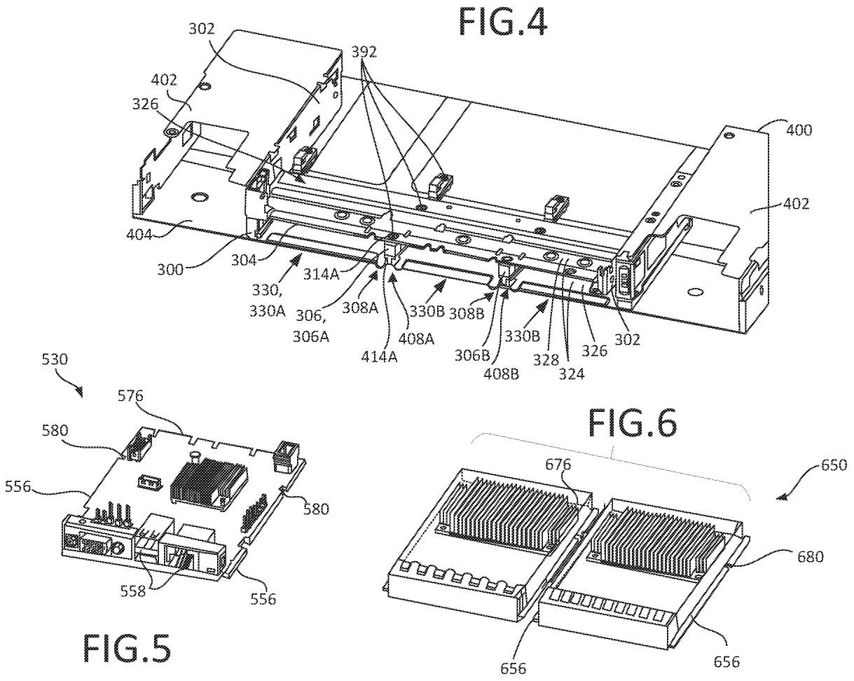

FIG. 4 depicts a perspective view of a first chassis 400 configured by a modular panel section 300 of FIG. 3A in a first configuration. The first chassis 400 includes a pair of component housings 402, a base 404, and the modular panel section 300.

In some examples, each component housing 402 may be a cage that is configured to house a corresponding electronic component, such as a power supply unit of the information processing device. The base 404 may extend between the pair of component housings 402 via the modular panel section 300. In other words, the modular panel section 300 is disposed between the pair of component housings 402 and configured to removably receive electronic components. In particular, the pair of vertical support members 302 is disposed spaced apart from each other and coupled to the base 404 such that the opening 324 (as shown in FIG. 1) is defined therebetween the pair of vertical support members 302. The horizontal support structure 304 extends between and coupled to the pair of vertical support members 302 to divide the opening 324 into the first region 326 and the second region 328 (as shown in FIG. 1).

Further, a first partition bracket 306A is disposed in the first region 326, for example, and at the first bracket mounting locations 308A, 408A and a second partition bracket 306B is also disposed in the first region 326, for example, and at second bracket mounting locations 308B, 408B, thereby dividing the first region 326 into a plurality of bays 330. In the illustrated example, the first chassis 400 includes three bays e.g., a first bay 330A and two second bays 330B. In such examples, the first bay 330A has a first width and each second bay 330B has a second width. In some examples, the first width is greater than the second width. In some examples, the first partition bracket 306A is removably connected to the horizontal support structure 304 by extending the fasteners 392 into the holes 313 (as shown in FIG. 3A) in the first mounting element 314A and into the holes 311 (as shown in FIG. 3B) in the top mounting feature 322A, and to the base 404 by extending fasteners (not shown) into the holes 415 (as shown in FIG. 3A) in the first mounting element 414A and into the holes (not shown) in the bottom mounting feature 320A. In one or more examples, a second partition bracket 306B is also removably connected to the horizontal support structure 304 and the base 404, as discussed hereinabove.

FIG. 5 depicts a perspective view of a first electronic module 550. In some examples, the first electronic module 550 is an open compute program (OCP) datacenter secure control module (DC SCM). Since the OCP DC SCM is a standard electronic module, it is not discussed in greater detail. The first electronic module 550 includes one or more first electrical connectors 576 disposed at a rear sub-panel and plurality of ports 578 at a front sub-panel. Further, the first electronic module 550 includes third guide members 556 extending along peripheral sidewalls of the first electronic module 550. In some examples, a groove 580 is formed on each of the third guide members 556 to allow the first electronic module 550 to be secured by the latching element. In one or more examples, the first electronic module 550 has a first form factor e.g., a first width which may be substantially equal to the first width of the first bay 330A (as shown in FIG. 4).

FIG. 6 depicts a perspective view of a plurality of second electronic modules 650. In some examples, each of the plurality of second electronic modules 650 is an SFF OCP NIC (small-form-factor OCP network interface card). Since the SFF OCP NIC is a standard electronic module, it is not discussed in greater detail. Each second electronic module 650 includes one or more first electrical connectors 676 disposed at a rear sub-panel and third guide members 656 extending along peripheral sidewalls of the second electronic module 650. In some examples, a groove 680 is formed on each of the third guide members 656 to allow the second electronic module 650 to be secured by the latching element. In one or more examples, each second electronic module 650 has a second form factor e.g., a second width which may be substantially equal to the second width of each of the second bays 330B (as shown in FIG. 4).

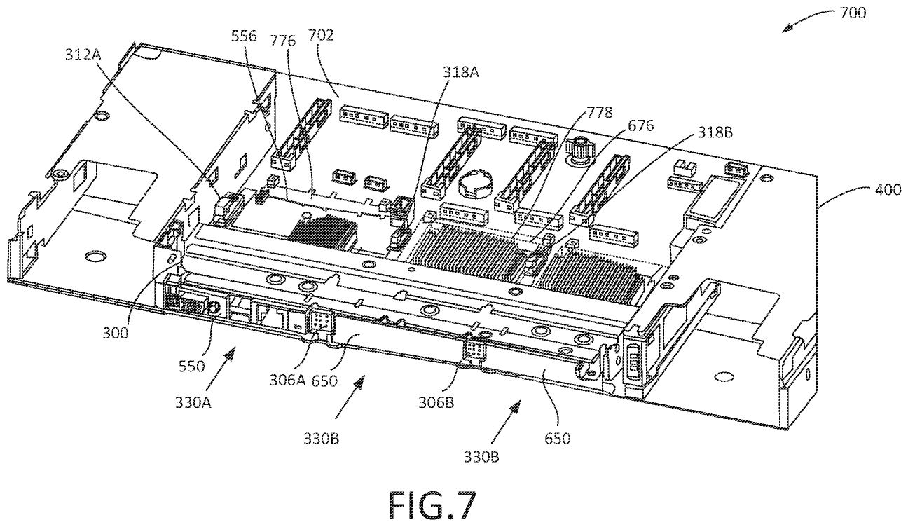

FIG. 7 depicts a perspective view of an information processing device 700 having the first chassis 400 of FIG. 4, and a primary system board 702, the first electronic module 550 of FIG. 5, and the plurality of second electronic modules 650 of FIG. 6.

In some examples, the first bay 330A is configured to slidably receive the first electronic module 550 having a first form factor, and each second bay 330B is configured to slidably receive the second electronic module among a plurality of second electronic modules 650, each having a second form factor. In particular, the first guide member 310A (as shown in FIG. 3A) of the first vertical support member 302A (as shown in FIG. 3A) and a second guide member 316A (as shown in FIG. 3A) of the first partition bracket 306A (as shown in FIG. 3A) are configured to engage with third guide members 556 (as shown in FIG. 5) of the first electronic module 550 as the first electronic module 550 is inserted into the first bay 330A to mount the first electronic module 550 to the first chassis 400 of the information processing device 700. In one or more examples, each of the plurality of second electronic modules 650 is also inserted into the corresponding second bay of the plurality of second bays 330B to mount the corresponding second electronic module 650 to the first chassis 400 of the information processing device 700, as discussed hereinabove.

In one or more examples, as the first electronic module 550 is inserted into the first bay 330A, the first latching element 312A and the second latching element 318A are configured to engage with the groove 580 (as shown in FIG. 5) in the first electronic module 550 and secure the first electronic module 550 to the first chassis 400. In one or more examples, each of the plurality of second electronic modules 650 is also secured to the first chassis 400 by the corresponding latching elements, as discussed hereinabove. Further, as the first electronic module 550 is disposed in the first bay 330A, the first electronic module 550 is electrically connected to the primary system board 702. In particular, the one or more first electrical connectors 576 of the first electronic module 550 is directly connected to one or more second electrical connectors 776 of the primary system board 702. In one or more examples, one or more first electrical connectors 676 of each second electronic module 650 is also directly connected to a corresponding one or more second electrical connectors 778 of the primary system board 702, as discussed hereinabove.

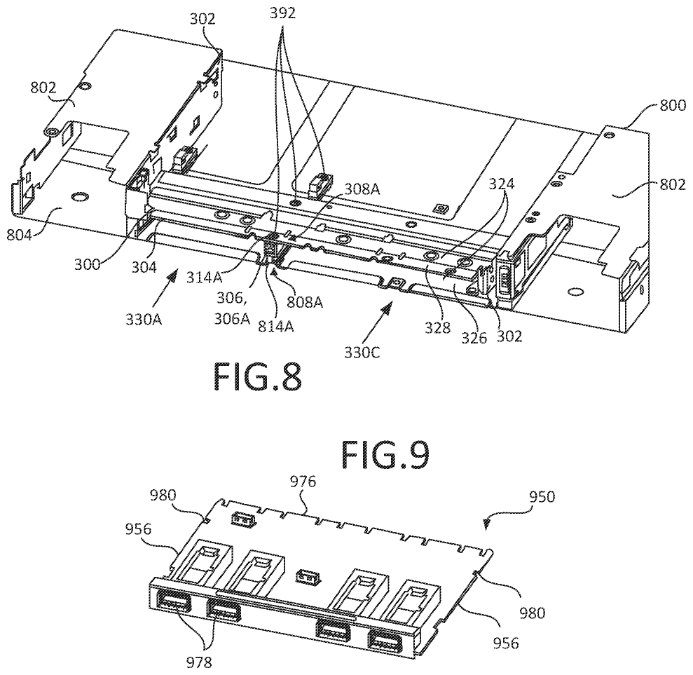

FIG. 8 depicts a perspective view of a second chassis 800 configured by a modular panel section 300 of FIG. 3A in a second configuration. The second chassis 800 includes a pair of component housings 802, a base 804, and the modular panel section 300.

In some examples, each component housing 802 may be a cage that is configured to house a corresponding electronic component, such as a power supply unit of the information processing device. The base 804 may extend between the pair of component housings 802 via the modular panel section 300. In other words, the modular panel section 300 is disposed between the pair of component housings 802. In particular, the pair of vertical support members 302 is disposed spaced apart from each other and coupled to the base 804 such that the opening 324 (as shown in FIG. 1) is defined therebetween the pair of vertical support members 302. The horizontal support structure 304 extends between and coupled to the pair of vertical support members 302 to divide the opening 324 into the first region 326 and the second region 328 (as shown in FIG. 1).

Further, a first partition bracket 306A is disposed in the first region 326, for example, and at first bracket mounting locations 308A, 808A, thereby dividing the first region 326 into a plurality of bays 330. In the illustrated example, the second chassis 800 includes two bays e.g., a first bay 330A and a third bay 330C. In such examples, the first bay 330A has a first width and the third bay 330C has a third width. In some examples, the third width is greater than the first width. In some examples, the first partition bracket 306A is removably connected to the horizontal support structure 304 by extending the fasteners 392 into the holes 313 (as shown in FIG. 3A) in the first mounting element 314A and into the holes 311 (as shown in FIG. 3B) in the top mounting feature 322A, and to the base 804 by extending fasteners (not shown) into the holes 815 (as shown in FIG. 3A) in first mounting element 814A and into the holes (not shown) in the bottom mounting feature 320A.

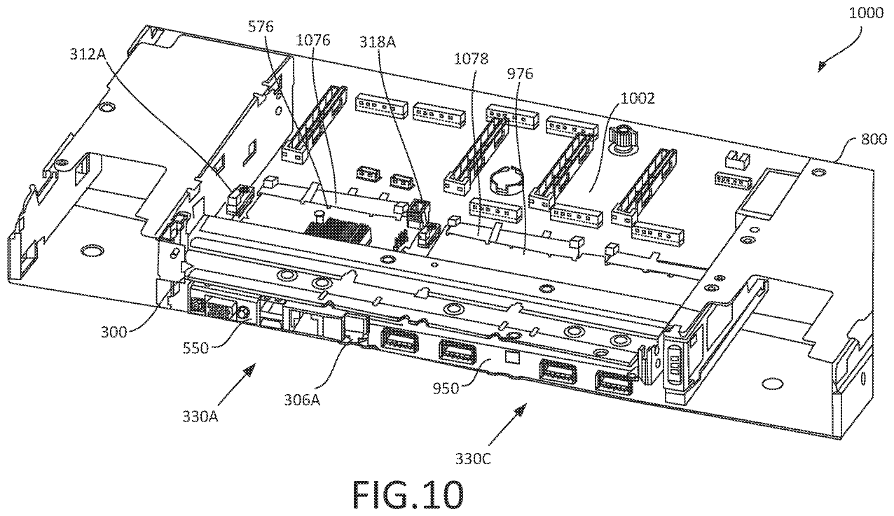

FIG. 9 depicts a perspective view of a third electronic module 950. In some examples, the third electronic module 950 is a doublewide or LFF (large form factor) OCP NIC). Since the doublewide or LFF OCP NIC is a standard electronic module, it is not discussed in greater detail. The third electronic module 950 includes one or more first electrical connectors 976 disposed at a rear sub-panel and plurality of ports 978 at a front sub-panel. Further, the third electronic module 950 includes third guide members 956 extending along peripheral sidewalls of the third electronic module 950. In some examples, a groove 980 is formed on each of the third guide members 956 to allow the third electronic module 950 to be secured by the latching element. In one or more examples, the third electronic module 950 has a third form factor e.g., a third width which is greater than the first width of the first bay 330A (as shown in FIG. 4) and equal to the third width of the third bay 330C.

FIG. 10 depicts a perspective view of an information processing device 1000 having the second chassis 800 of FIG. 8, and a primary system board 1002, the first electronic module 550 of FIG. 5, and the third electronic module 950 of FIG. 9.

In some examples, a first bay 330A is configured to slidably receive the first electronic module 550 having a first form factor, and the third bay 330C is configured to slidably receive the third electronic module 950, having the third form factor. In particular, the first guide member 310A (as shown in FIG. 3A) of the first vertical support member 302A (as shown in FIG. 3A) and a second guide member 316A (as shown in FIG. 3A) of the first partition bracket 306A (as shown in FIG. 3A) are configured to engage with third guide members 556 (as shown in FIG. 5) of the first electronic module 550 as the first electronic module 550 is inserted into the first bay 330A to mount the first electronic module 550 to the second chassis 800 of the information processing device 700. In one or more examples, the third electronic module 950 is also inserted into the third bay 330C to mount the third electronic module 950 to the second chassis 800, as discussed hereinabove.

In one or more examples, as the first electronic module 550 is inserted into the first bay 330A, the first latching element 312A and the second latching element 318A are configured to engage with the groove 580 (as shown in FIG. 5) in the first electronic module 550 and secure the first electronic module 550 to the second chassis 800. In one or more examples, the third electronic module 950 is also secured to the second chassis 800 by the corresponding latching elements, as discussed hereinabove. Further, as the first electronic module 550 is disposed in the first bay 330A, the first electronic module 550 is electrically connected to the primary system board 1002. In particular, one or more first electrical connectors 576 of the first electronic module 550 are directly connected to one or more second electrical connectors 1076 of the primary system board 1002. In one or more examples, one or more first electrical connectors 976 of the third electronic module 950 is also directly connected to one or more second electrical connectors 1078 of the primary system board 1002, as discussed hereinabove.

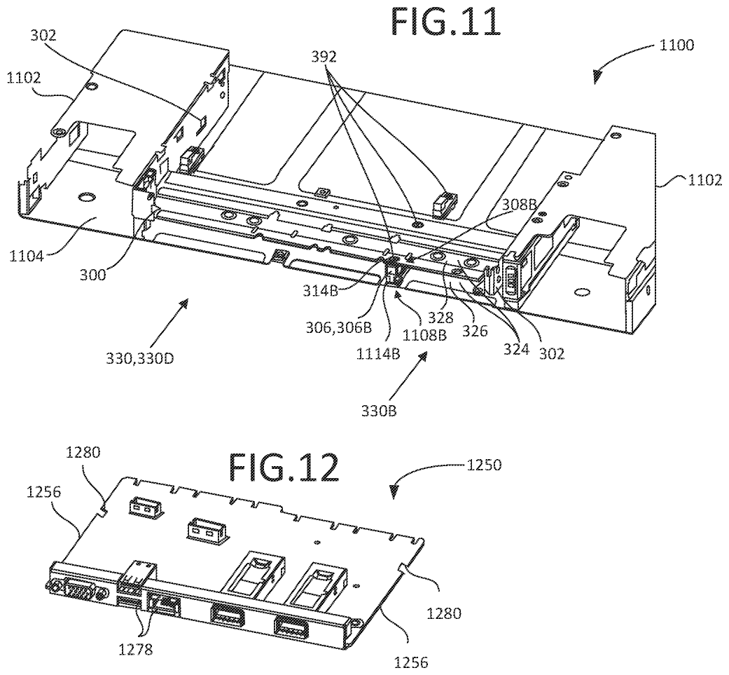

FIG. 11 depicts a perspective view of a third chassis 1100 configured by a modular panel section 300 of FIG. 3A in a third configuration. The third chassis 1100 includes a pair of component housings 1102, a base 1104, and the modular panel section 300.

In some examples, each component housing 1102 may be a cage that is configured to house a corresponding electronic component, such as a power supply unit of the information processing device. The base 1104 may extend between the pair of component housings 1102 via the modular panel section 300. In other words, the modular panel section 300 is disposed between the pair of component housings 1102. In particular, the pair of vertical support members 302 is disposed spaced apart from each other and coupled to the base 1104 such that the opening 324 (as shown in FIG. 1) is defined therebetween the pair of vertical support members 302. The horizontal support structure 304 extends between and coupled to the pair of vertical support members 302 to divide the opening 324 into the first region 326 and the second region 328 (as shown in FIG. 1).

Further, a second partition bracket 306B is disposed in the first region 326, for example, and at second bracket mounting locations 308B, 1108B, thereby dividing the first region 326 into a plurality of bays 330. In the illustrated example, the third chassis 1100 includes two bays e.g., a fourth bay 330D and a second bay 330B. In such examples, the fourth bay 330D has a fourth width and the second bay 330B has a second width. In some examples, the fourth width is greater than the second width. In some examples, the second partition bracket 306B is removably connected to the horizontal support structure 304 by extending the fasteners 392 into the holes 313 (as shown in FIG. 3A) in the first mounting element 314B and into the holes 311 (as shown in FIG. 3A) in the top mounting feature 322B, and to the base 1104 by extending fasteners (not shown) into the holes 815 (as shown in FIG. 3A) in first mounting element 1114B and into the holes (not shown) in the bottom mounting feature 320B.

FIG. 12 depicts a perspective view of a fourth electronic module 1250. In some examples, the fourth electronic module 1250 is an OCP PCM (platform control module). Since the OCP PCM is a standard electronic module, it is not discussed in greater detail. The fourth electronic module 1250 includes one or more first electrical connectors 1276 disposed at a rear sub-panel and plurality of ports 1278 at a front sub-panel. Further, the fourth electronic module 1250 includes third guide members 1256 extending along peripheral sidewalls of the fourth electronic module 1250. In some examples, a groove 1280 is formed on each of the third guide members 1256 to allow the fourth electronic module 1250 to be secured by the latching element. In one or more examples, the fourth electronic module 1250 has a fourth form factor e.g., a fourth width which is greater than the second width of the second bay 330B (as shown in FIG. 4).

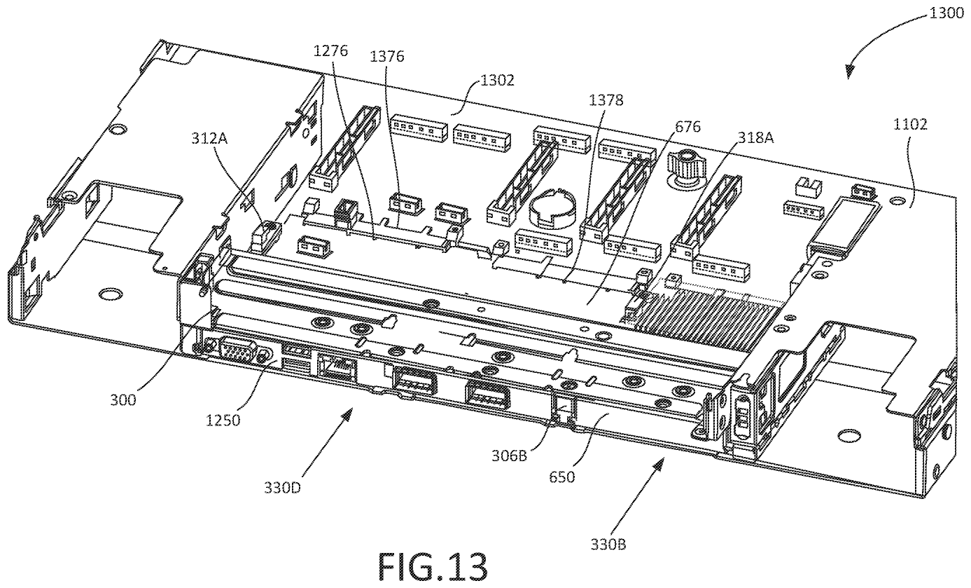

FIG. 13 depicts a perspective view of an information processing device 1300 having the third chassis 1100 of FIG. 11, and a primary system board 1302, the fourth electronic module 1250 of FIG. 12, and the second electronic module 650 of FIG. 6.

In some examples, a first bay 330A is configured to slidably receive the fourth electronic module 1250 having a fourth form factor, and the second bay 330B is configured to slidably receive the second electronic module 650, having the second form factor. In particular, the first guide member 310A (as shown in FIG. 3A) of the first vertical support member 302A (as shown in FIG. 3A) and a second guide member 316A (as shown in FIG. 3A) of the first partition bracket 306A (as shown in FIG. 3A) are configured to engage with third guide members 1256 (as shown in FIG. 12) of the fourth electronic module 1250 as the fourth electronic module 1250 is inserted into the fourth bay 330D to mount the fourth electronic module 1250 to the third chassis 1100 of the information processing device 1300. In one or more examples, the second electronic module 650 is also inserted into the second bay 330B to mount the second electronic module 650 to the third chassis 1100, as discussed hereinabove.

In one or more examples, as the fourth electronic module 1250 is inserted into the fourth bay 330D, the first latching element 312A and the second latching element 318A are configured to engage with the groove 1280 (as shown in FIG. 12) in the fourth electronic module 1250 and secure the fourth electronic module 1250 to the third chassis 1100. In one or more examples, the second electronic module 650 is also secured to the third chassis 1100 by the corresponding latching elements, as discussed hereinabove. Further, as the fourth electronic module 1250 is disposed in the fourth bay 330D, the fourth electronic module 1250 is electrically connected to the primary system board 1302. In particular, one or more first electrical connectors 1276 of the fourth electronic module 1250 are directly connected to one or more second electrical connectors 1376 of the primary system board 1302. In one or more examples, one or more first electrical connectors 676 of the second electronic module 650 are also directly connected to one or more second electrical connectors 1378 of the primary system board 1302, as discussed hereinabove.

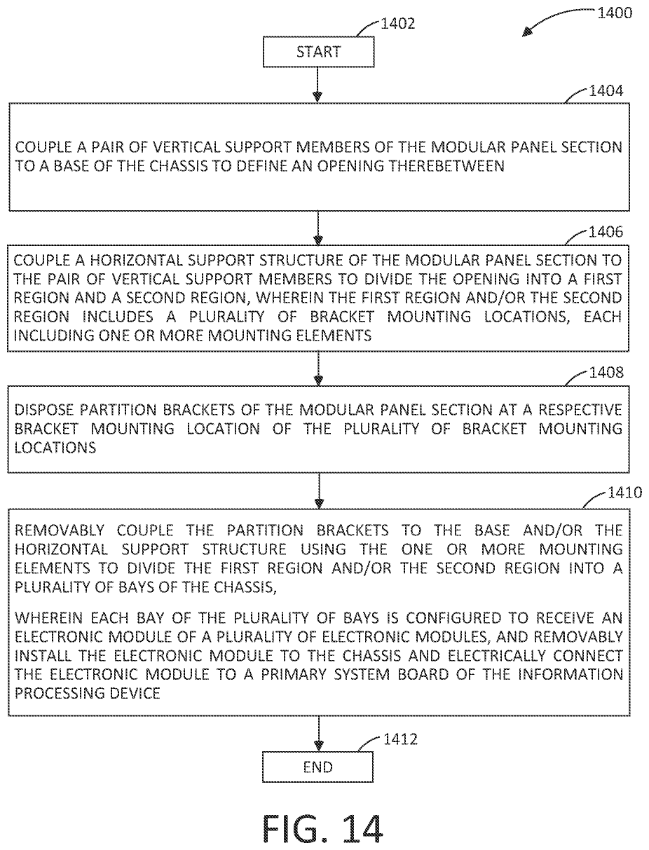

FIG. 14 depicts a flow depicting a method 1400 of configuring a chassis of an information processing device by a modular panel section. It may be noted herein that the method 1400 is described in conjunction with FIGS. 1 and 2A-2D, and FIGS. 3A-3B and 4-13, for example. The method 1400 starts at block 1402 and continues to block 1404.

At block 1404, the method 1400 includes coupling a pair of vertical support members of the modular panel section to a base of the chassis to define an opening therebetween. The method 1400 continues to block 1406. At block 1406, the method 1400 includes coupling a horizontal support structure of the modular panel section to the pair of vertical support members to divide the opening into a first region and a second region, wherein the first region and/or the second region includes a plurality of bracket mounting locations, each including one or more mounting elements. The method 1400 continues to block 1408. At block 1408, the method 1400 includes disposing partition brackets of the modular panel section at a respective bracket mounting location of the plurality of bracket mounting locations. The method 1400 continues to block 1410. At block 1410, the method 1400 includes removably coupling the partition brackets to the base and/or the horizontal support structure using the one or more mounting elements to divide the first region and/or the second region into a plurality of bays of the chassis. each bay of the plurality of bays is configured to receive an electronic module of a plurality of electronic modules, and removably install the electronic module to the chassis and electrically connect the electronic module to a primary system board of the information processing device.

In some examples, the method 1400 further includes reconfiguring the chassis using the modular panel section. For example, at least one of respective sizes of the bays, respective locations of the bays, or a number of the bays among the plurality of bays is reconfigurable by at least one of: disposing an additional partition bracket at one of the plurality of bracket mounting locations or removing one of the partition brackets, or changing which of the plurality of bracket mounting locations the partition brackets are installed at. The method ends at block 1412.

In the foregoing description, numerous details are set forth to provide an understanding of the subject matter disclosed herein. However, implementation may be practiced without some or all these details. Other implementations may include modifications, combinations, and variations from the details discussed above. It is intended that the following claims cover such modifications and variations.

What is claimed is:

1. A chassis of an information processing device, comprising:
a base;
a modular panel section comprising:
a pair of vertical support members coupled to the base and defining an opening therebetween;
a horizontal support structure extending between and coupled to the pair of vertical support members to divide the opening into a first region and a second region;
one or more partition brackets; and
a plurality of bracket mounting locations in the first region and/or in the second region, wherein each of the bracket mounting locations comprises one or more mounting elements configured to, on condition of one of the partition brackets being disposed at a respective bracket mounting location, connect a respective partition bracket to the base and/or the horizontal support structure,
wherein the partition brackets are disposed at respective bracket mounting locations of the plurality of bracket mounting locations and removably coupled to the base and/or to the horizontal support structure and divide the first region and/or the second region into a plurality of bays, and
wherein each bay of the plurality of bays is configured to receive an electronic module of a plurality of electronic modules and allow the electronic module to be electrically connected to a primary system board of the information processing device.

2. The chassis of claim 1, wherein at least one of respective sizes of the bays, respective locations of the bays, or a number of the bays among the plurality of bays is reconfigurable by at least one of:
disposing an additional partition bracket at one of the plurality of bracket mounting locations or removing one of the partition brackets; or
changing which of the plurality of bracket mounting locations the one or more partition brackets are installed at.

3. The chassis of claim 1, wherein each vertical support member of the pair of vertical support members comprises a first guide member, wherein each partition bracket comprises second guide members, wherein the first guide members and the second guide members are configured to engage with third guide members of the electronic module as the plurality of electronic modules is inserted into the plurality of bays to mount the plurality of electronic modules to the information processing device.

4. The chassis of claim 3, wherein a first bay of the plurality of bays is defined between a first vertical support member and a first partition bracket, and wherein the first guide member of the first vertical support member and the second guide member of the first partition bracket are configured to engage with the third guide members of a first electronic module of the plurality of electronic modules to mount the first electronic module to the information processing device.

5. The chassis of claim 4, wherein a second bay of the plurality of bays is defined between a first partition bracket and a second partition bracket, and wherein the second guide members of first and second partition brackets are configured to engage with the third guide members of a second electronic module of the plurality of electronic modules to mount the second electronic module to the information processing device.

6. The chassis of claim 1, further comprising a pair of component housings, each configured to house an electronic component of the information processing device, and wherein one vertical support member of the pair of vertical support members is part of one component housing of the pair of component housings.

7. The chassis of claim 1, wherein each partition bracket and/or vertical support member comprises a latching element configured to secure a corresponding electronic module of the plurality of electronic modules received in a corresponding bay of the plurality of bays.

8. The chassis of claim 1, wherein the modular panel section forms or is a part of a rear panel of the information processing device.

9. The chassis of claim 1, wherein each partition bracket has a half U space height, and wherein each bay formed in the second region allows the electronic module to be electrically connected to the primary system board via one or more cables.

10. An information processing device comprising:
a chassis comprising a base and a modular panel section;
a plurality of electronic modules configured to removably install in the chassis through the modular panel section, each electronic module comprising one or more first electrical connectors; and
a primary system board coupled to the base and comprising one or more second electrical connectors,
wherein the modular panel section comprises:
a pair of vertical support members coupled to the base and defining an opening therebetween;
a horizontal support structure extending between and coupled to the pair of vertical support members to divide the opening into a first region and a second region;
one or more partition brackets; and
a plurality of bracket mounting locations in the first region and/or in the second region, wherein each of the bracket mounting locations comprises one or more mounting elements configured to, on condition of one of the partition brackets being disposed at a respective bracket mounting location, connect a respective partition bracket to the base and/or the horizontal support structure,
wherein the partition brackets are disposed at respective bracket mounting locations of the plurality of bracket mounting locations and removably coupled to the base and/or to the horizontal support structure and divide the first region and/or the second region into a plurality of bays, and
wherein each bay of the plurality of bays located in one of the first or second regions is aligned to the one or more second electrical connectors and is configured to receive a corresponding electronic module of the plurality of electronic modules and allow the one or more first electrical connectors to be electrically connected to corresponding one or more second electrical connectors.

11. The information processing device of claim 10, wherein at least one of respective sizes of the bays, respective locations of the bays, or a number of the bays among the plurality of bays is reconfigurable by at least one of:
disposing an additional partition bracket at one of the plurality of bracket mounting locations or removing one of the partition brackets; or
changing which of the plurality of bracket mounting locations the one or more partition brackets are installed at.

12. The information processing device of claim 10, wherein each vertical support member of the pair of vertical support members comprises a first guide member, wherein each partition bracket comprises second guide members, wherein the first guide members and the second guide members are configured to engage with third guide members of the corresponding electronic module as the plurality of electronic modules is inserted into the plurality of bays to mount the plurality of electronic modules to the information processing device.

13. The information processing device of claim 12, wherein a first bay of the plurality of bays is defined between a first vertical support member and a first partition bracket, and wherein the first guide member of the first vertical support member and the second guide member of the first partition bracket are configured to engage with the third guide members of a first electronic module of the plurality of electronic modules to mount the first electronic module to the information processing device.

14. The information processing device of claim 13, wherein a second bay of the plurality of bays is defined between a first partition bracket and a second partition bracket, and wherein the second guide members of first and second partition brackets are configured to engage with the third guide members of a second electronic module of the plurality of electronic modules to mount the second electronic module to the information processing device.

15. The information processing device of claim 10, wherein the chassis further comprises a pair of component housings configured to removably receive electronic components, and wherein each vertical support member of the pair of vertical support members is a part of a corresponding component housing.

16. The information processing device of claim 10, wherein each partition bracket and/or vertical support member comprises a latching element configured to secure the corresponding electronic module received in a corresponding bay of the plurality of bays.

17. The information processing device of claim 10, wherein the modular panel section forms or is a part of a rear panel of the information processing device.

18. The information processing device of claim 10, wherein each partition bracket has a half U space height, and wherein each bay formed in the second region allows the corresponding electronic module to be electrically connected to the primary system board via one or more cables.

19. A method of configuring a chassis of an information processing device by a modular panel section, comprising:
coupling a pair of vertical support members of the modular panel section to a base of the chassis to define an opening therebetween;
coupling a horizontal support structure of the modular panel section to the pair of vertical support members to divide the opening into a first region and a second region, wherein the first region and/or the second region comprises a plurality of bracket mounting locations, each comprising one or more mounting elements;
disposing partition brackets of the modular panel section at a respective bracket mounting location of the plurality of bracket mounting locations; and
removably coupling the partition brackets to the base and/or the horizontal support structure using the one or more mounting elements to divide the first region and/or the second region into a plurality of bays of the chassis,
wherein each bay of the plurality of bays is configured to receive an electronic module of a plurality of electronic modules, and removably install the electronic module to the chassis and electrically connect the electronic module to a primary system board of the information processing device.

20. The method of claim 19, wherein at least one of respective sizes of the bays, respective locations of the bays, or a number of the bays among the plurality of bays is reconfigurable by at least one of:
disposing an additional partition bracket at one of the plurality of bracket mounting locations or removing one of the partition brackets; or
changing which of the plurality of bracket mounting locations the partition brackets are installed at.
